(19) United States
(12) Patent Application Publication
(10) Pub. No.: US 2026/0090099 A1
(43) Pub. Date: Mar. 26, 2026

(54) SEMICONDUCTOR DEVICE HAVING A HIGH BREAKDOWN VOLTAGE AND A LOW ON RESISTANCE, AND METHOD FOR MANUFACTURING THE SAME

(71) Applicant: TAIWAN SEMICONDUCTOR MANUFACTURING COMPANY, LTD., Hsinchu (TW)

(72) Inventors: Yun-Chi WU, Hsinchu (TW); Po-Wei LIU, Hsinchu (TW); Chia-Ta HSIEH, Hsinchu (TW); Hsin Fu LIN, Hsinchu (TW); Shiang-Hung HUANG, Hsinchu (TW)

(73) Assignee: TAIWAN SEMICONDUCTOR MANUFACTURING COMPANY, LTD., Hsinchu (TW)

(21) Appl. No.: 18/896,552

(22) Filed: Sep. 25, 2024

(51) Int. Cl. H01L 27/12; H01L 21/762; H01L 21/84

(52) U.S. Cl. CPC H10D 86/201; H10D 86/01; H10P 90/1906; H10W 10/014; H10W 10/061; H10W 10/17; H10W 10/181

(57) ABSTRACT

A semiconductor device includes a semiconductor layer, a drift region formed in the semiconductor layer, and a dielectric film formed in the drift region. The drift region includes a first side well, a second side well and a well stack. The first side well has a first type conductivity. The second side well has the first type conductivity. The well stack is disposed laterally between the first side well and the second side well, and includes a plurality of intermediate wells that are stacked from top to bottom. A topmost one of the intermediate wells has a second type conductivity opposite to the first type conductivity, and covers bottom and side surfaces of the dielectric film. Two adjacent ones of the intermediate wells have different type conductivities.

### BACKGROUND

The semiconductor integrated circuit (IC) industry has, over the decades, experienced tremendous advancements and is still undergoing vigorous development. With dramatic advances in technology, the industry pays much attention to the development of transistors having high breakdown voltages and low ON resistances for high voltage applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view of a semiconductor device in accordance with some embodiments.

FIG. 2 is a schematic sectional view of a semiconductor device in accordance with some embodiments.

FIG. 3 is a schematic sectional view of a semiconductor device in accordance with some embodiments.

FIG. 4 is a schematic sectional view of a semiconductor device in accordance with some embodiments.

FIG. 5 is a flow chart illustrating a method for manufacturing a semiconductor device in accordance with some embodiments.

FIGS. 6 to 13 are schematic sectional views illustrating intermediate stages of a method for manufacturing a semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

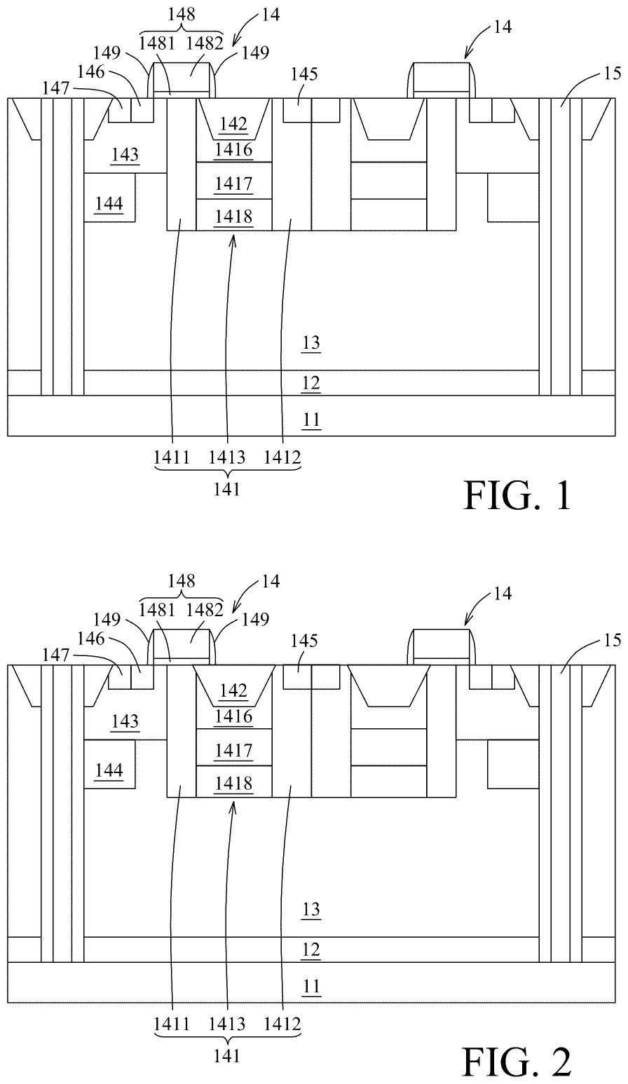

FIG. 1 is a schematic sectional view of a semiconductor device in accordance with some embodiments. Referring to FIG. 1, the semiconductor device includes a substrate 11, a buried isolation layer 12, a semiconductor layer 13, a plurality of transistors 14 and an isolation feature 15. It should be noted that only two of the transistors 14 are depicted in FIG. 1. The substrate 11 has, for example, a p-type conductivity. The buried isolation layer 12 is disposed on the substrate 11. The semiconductor layer 13 is disposed on the buried isolation layer 12, and has, for example, the p-type conductivity. The transistors 14 are formed on the semiconductor layer 13. The isolation feature 15 penetrates the semiconductor layer 13 and the buried isolation layer 12, encloses the transistors 14, and cooperates with the buried isolation layer 12 to provide electrical isolation effect to the transistors 14.

Each of the transistors 14 is, for example, an n-channel laterally diffused metal oxide semiconductor (LDMOS) field effect transistor, and includes a drift region 141, a dielectric film 142, a first well region 143, a second well region 144, a drain region 145, a source region 146, a bulk region 147, a gate structure 148 and two gate spacers 149. With respect to each of the transistors 14, the drift region 141 is formed in the semiconductor layer 13. The dielectric film 142 is formed in the drift region 141. Each of the drift regions 141 includes a first side well 1411, a second side well 1412 and a well stack 1413. Each of the first side well 1411 and the second side well 1412 has an n-type conductivity. The well stack 1413 is disposed between the first side well 1411 and the second side well 1412, and includes a first intermediate well 1416, a second intermediate well 1417 and a third intermediate well 1418. The first intermediate well 1416, the second intermediate well 1417 and the third intermediate well 1418 are laterally disposed and stacked from top to bottom in the given order. The first intermediate well 1416 has the p-type conductivity, and covers bottom and side surfaces of the dielectric film 142. The second intermediate well 1417 has the n-type conductivity. The third intermediate well 1418 has the p-type conductivity. The drift region 141 is configured in such a way that: a bottom surface of the dielectric film 142 is in contact with the first intermediate well 1416, and is spaced apart from the second intermediate well 1417 by the first intermediate well 1416; and each of two opposite side surfaces of the dielectric film 142 is in contact with the first intermediate well 1416, and is spaced apart by the first intermediate well 1416 from one the first side well 1411 and the second side well 1412 that faces the side surface of the dielectric film 142. The first well region 143 is formed in the semiconductor layer 13, is disposed aside the first side well 1411 and opposite to the well stack 1413, and has the p-type conductivity. A bottom surface of the first well region 143 is higher than a bottom surface of the first side well 1411. The second well region 144 is formed in the semiconductor layer 13, is disposed below the first well region 143, is spaced apart from the first side well 1411 by the semiconductor layer 13, and has the p-type conductivity. The drain region 145 is formed in the second side well 1412, and has the n-type conductivity. The source region 146 is formed in the first well region 143, is spaced apart from the first side well 1411 by the first well region 143, and has the n-type conductivity. The bulk region 147 is formed in the first well region 143, and has the p-type conductivity. The gate structure 148 is disposed over a portion of the first well region 143 that is between the first side well 1411 and the source region 146, and includes a gate dielectric 1481 and a gate electrode 1482. The gate electrode 1482 is disposed on the gate dielectric 1481, and is spaced apart by the gate dielectric 1481 from the portion of the first well region 143 that is between the first side well 1411 and the source region 146. The gate spacers 149 laterally cover the gate dielectric 1481 and the gate electrode 1482.

With respect to each of the transistors 14, in operation, electrons would flow through the source region 146, the first well region 143, the first side well 1411, the second intermediate well 1417, the second side well 1412 and the drain region 145 in the given order when the transistor 14 conducts. Since the dielectric film 142 is spaced apart from the source region 146, the first well region 143, the first side well 1411, the second intermediate well 1417, the second side well 1412 and the drain region 145, the electrons would not impact the dielectric film 142 when the transistor 14 is in operation, so hot carrier injection can be prevented and reliability of the transistor 14 can be enhanced. In addition, the well stack 1413 would deplete completely, so charge balance can be attained, thereby ensuring safe operation of the transistor 14 (i.e., raising a breakdown voltage of the transistor 14 and reducing an ON resistance of the transistor 14).

In some embodiments, a volume of the second well region 144 may be smaller than a volume of the first well region 143. It should be noted that a combination of the first side well 1411, the second side well 1412 and the second intermediate well 1417, a combination of the first well region 143 and the second well region 144, and the source region 146 would cooperatively constitute a parasitic NPN bipolar junction transistor (BJT). Because of the inclusion of the second well region 144 that is spaced apart from the first side well 1411 and that is smaller than the first well region 143 in volume, a base resistance and a threshold voltage of the parasitic NPN BJT can be small, which lowers the probability of the parasitic NPN BJT becoming conducting.

In some embodiments, with respect to each of the transistors 14, the dielectric film 142 may be a shallow trench isolation (STI); each of the first side well 1411, the second side well 1412, the first intermediate well 1416, the second intermediate well 1417 and the third intermediate well 1418 may be a high voltage well; the first well region 143 may be a high voltage well region; and the second well region 144 may be a low voltage well region. In addition, the isolation feature 15 may be a combination of a STI and a deep trench isolation (DTI).

FIG. 2 is a schematic sectional view of a semiconductor device in accordance with some embodiments. Referring to FIG. 2, the semiconductor device depicted in FIG. 2 is similar to the semiconductor device depicted in FIG. 1, but differs from the semiconductor device depicted in FIG. 1 in that: with respect to each of the transistors 14, the drift region 141 is configured in such a way that each of the side surfaces of the dielectric film 142 is in contact with not only the first intermediate well 1416 but also one the first side well 1411 and the second side well 1412 that faces the side surface of the dielectric film 142. In other words, for each of the side surfaces of the dielectric film 142, a first portion of the side surface of the dielectric film 142 that is close to the bottom surface of the dielectric film 142 is in contact with the first intermediate well 1416, and a second portion of the side surface of the dielectric film 142 that is close to a top surface of the dielectric film 142 is in contact with said one the first side well 1411 and the second side well 1412 that faces the side surface of the dielectric film 142.

With respect to each of the transistors 14, since each of the side surfaces of the dielectric film 142 is partially, but not completely, contacting the first side well 1411, the dielectric film 142 is less likely to be impacted by electrons when the transistor 14 is operating, so hot carrier injection can be alleviated and reliability of the transistor 14 can be enhanced.

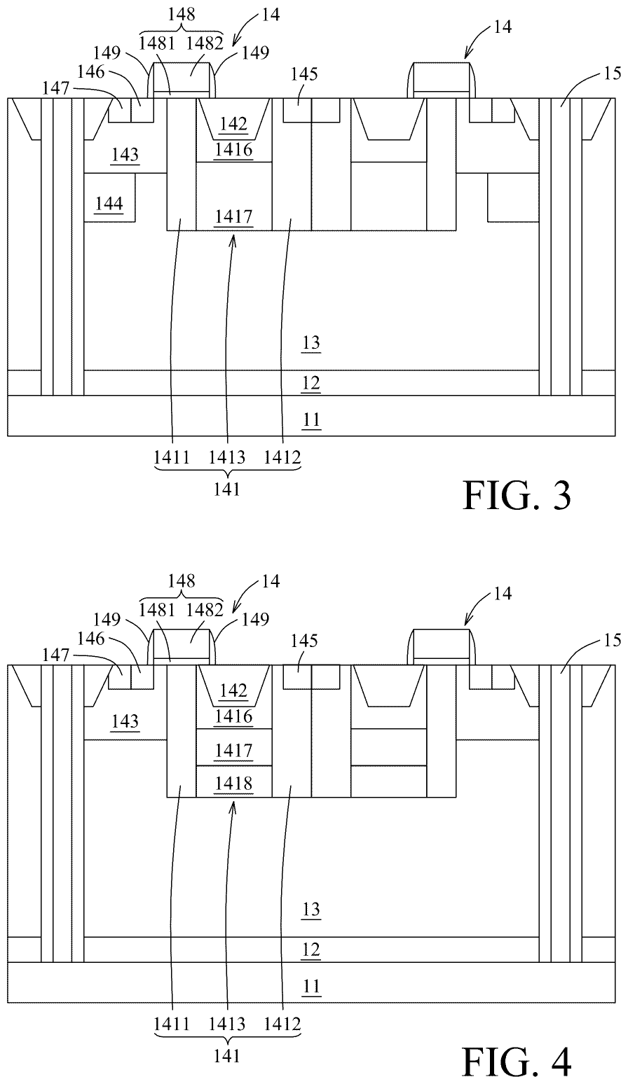

FIG. 3 is a schematic sectional view of a semiconductor device in accordance with some embodiments. Referring to FIG. 3, the semiconductor device depicted in FIG. 3 is similar to the semiconductor device depicted in FIG. 1, but differs from the semiconductor device depicted in FIG. 1 in that: with respect to each of the transistors 14, the third intermediate well 1418 (see FIG. 1) is omitted in the well stack 1413 (i.e., the well stack 1413 includes two intermediate wells 1416, 1417). It should be noted that, in some other embodiments, with respect to each of the transistors 14, the well stack 1413 may include more than three intermediate wells, a top most one of the intermediate wells may have the p-type conductivity, and any two adjacent ones of the intermediate wells may have different type conductivities.

FIG. 4 is a schematic sectional view of a semiconductor device in accordance with some embodiments. Referring to FIG. 4, the semiconductor device depicted in FIG. 4 is similar to the semiconductor device depicted in FIG. 1, but differs from the semiconductor device depicted in FIG. 1 in that each of the transistors 14 is a p-channel LDMOS field effect transistor instead of the n-channel LDMOS field effect transistor.

In the semiconductor device depicted in FIG. 4, with respect to each of the transistors 14: the first side well 1411, the second side well 1412, the second intermediate well 1417, the drain region 145 and the source region 146 have the p-type conductivity instead of the n-type conductivity; the first intermediate well 1416, the third intermediate well 1418, the first well region 143 and the bulk region 147 have the n-type conductivity instead of the p-type conductivity; and the second well region 144 are omitted.

With respect to each of the transistors 14, in operation, holes would flow through the source region 146, the first well region 143, the first side well 1411, the second intermediate well 1417, the second side well 1412 and the drain region 145 in the given order when the transistor 14 conducts. Since the dielectric film 142 is spaced apart from the source region 146, the first well region 143, the first side well 1411, the second intermediate well 1417, the second side well 1412 and the drain region 145, the holes would not impact the dielectric film 142 when the transistor 14 is in operation, so hot carrier injection can be prevented and reliability of the transistor 14 can be enhanced. In addition, the well stack 1413 would deplete completely, so charge balance can be attained, thereby ensuring safe operation of the transistor 14 (i.e., raising a breakdown voltage of the transistor 14 and reducing an ON resistance of the transistor 14).

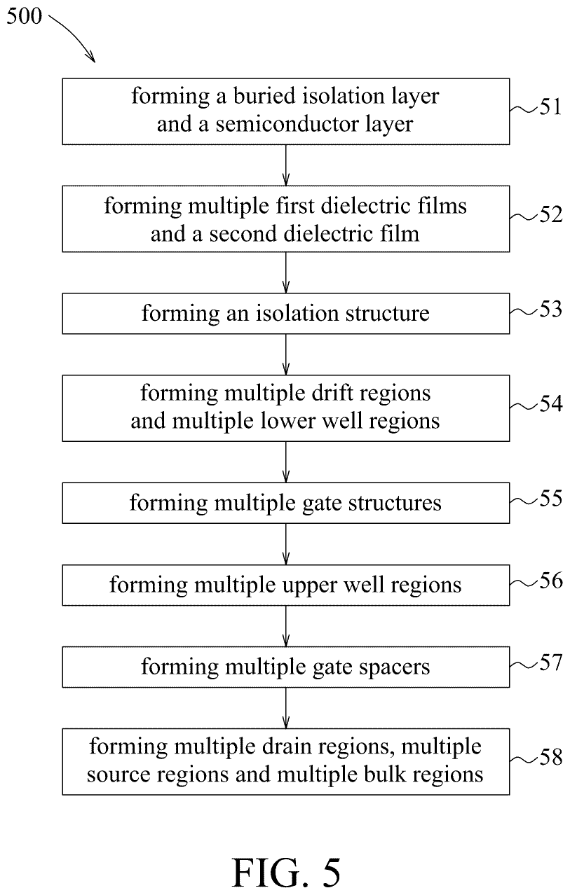

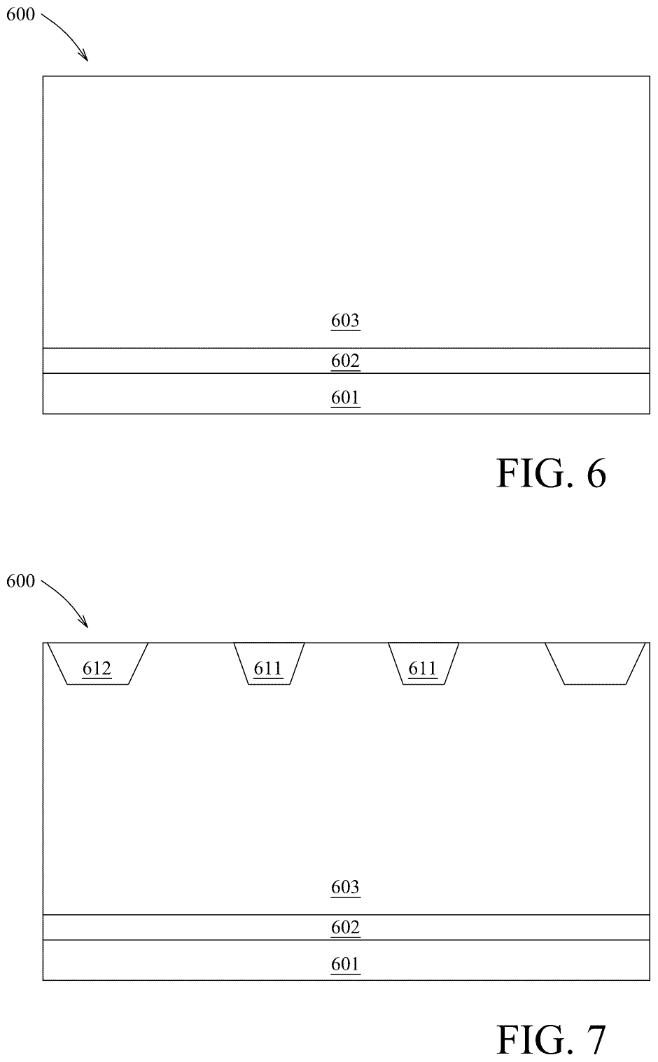

FIG. 5 is a flow chart illustrating a method 500 for manufacturing a semiconductor device in accordance with some embodiments. FIGS. 6 to 13 are schematic sectional views of semiconductor structures 600 during various stages of the method 500. The method 500 and the semiconductor structures 600 will be described together below. It should be noted that additional steps can be provided before, during or after the method 500, and some of the steps described herein may be replaced by other steps or be eliminated. Similarly, further additional features may be present in the semiconductor structures 600, and/or features present may be replaced or eliminated in additional embodiments.

Referring to FIGS. 5 and 6, the method 500 begins at step 51, where a buried isolation layer 602 and a semiconductor layer 603 are sequentially formed on a substrate 601. The substrate 601 would serve as the substrate 11 of the semiconductor device depicted in FIG. 1. The buried isolation layer 602 would serve as the buried isolation layer 12 of the semiconductor device depicted in FIG. 1. The semiconductor layer 603 would serve as the semiconductor layer 13 of the semiconductor device depicted in FIG. 1. In some embodiments, the buried isolation layer 602 may be formed on the substrate 601 by a suitable deposition process known in the art of semiconductor fabrication, such as physical vapor deposition (PVD), chemical vapor deposition (CVD), atomic layer deposition (ALD), plasma-enhanced chemical vapor deposition (PECVD), plasma-enhanced atomic layer deposition (PEALD), other suitable techniques, or combinations thereof. In some embodiments, the semiconductor layer 601 may be formed on the buried isolation layer 602 by a suitable deposition process known in the art of semiconductor fabrication, such as epitaxial growth, other suitable techniques, or combinations thereof. In some embodiments, the substrate 601 may be made of elemental semiconductor materials (e.g., crystalline silicon (Si), diamond, germanium (Ge) or the like), compound semiconductor materials (e.g., gallium nitride (GaN), silicon carbide (SiC), gallium arsenide (GaAs), indium arsenide (InAs), indium phosphide (InP) or the like), or alloy semiconductor materials (e.g., silicon germanium (SiGe), silicon germanium carbide, gallium arsenic phosphide (GaAsP), gallium indium phosphide (GaInP) or the like). The material for forming the substrate 601 may be doped with p-type impurities (e.g., boron (B), aluminum (Al), gallium (Ga) or the like) or n-type impurities (e.g., phosphorous (P), antimony (Sb), arsenic (As) or the like), or undoped. In addition, the substrate 601 may be a bulk silicon substrate, a silicon-on-insulator (SOI) substrate, or a germanium-on-insulator (GOI) substrate. Other suitable materials and/or configurations for the substrate 601 are within the contemplated scope of the present disclosure. In some embodiments, the buried insulation layer 602 may include, for example, oxide (e.g., silicon oxide or the like), other suitable materials, or combinations thereof. In some embodiments, the semiconductor layer 603 may be doped with p-type impurities (e.g., boron (B), aluminum (Al), gallium (Ga) or the like), or may alternatively be doped with n-type impurities (e.g., phosphorous (P), antimony (Sb), arsenic (As) or the like).

Referring to FIGS. 5 and 7, the method 500 then proceeds to step 52, where a plurality of first dielectric films 611 and a second dielectric film 612 are formed in the semiconductor layer 603. The first dielectric films 611 would respectively serve as the dielectric films 142 of the transistors 14 of the semiconductor device depicted in FIG. 1. The second dielectric film 612 encloses the first dielectric films 611. In some embodiments, the first dielectric films 611 and the second dielectric film 612 may be formed by: (a) etching the semiconductor layer 603 to form a plurality of recesses using, for example, dry etching, wet etching, reactive ion etching (RIE), atomic layer etching (ALE), other suitable techniques, or combinations thereof; (b) depositing a dielectric layer for forming the first dielectric films 611 and the second dielectric film 612 on the semiconductor layer 603 using, for example, physical vapor deposition (PVD), chemical vapor deposition (CVD), atomic layer deposition (ALD), plasma-enhanced chemical vapor deposition (PECVD), plasma-enhanced atomic layer deposition (PEALD), other suitable techniques, or combinations thereof; and (c) removing an excess of the dielectric layer using, for example, chemical mechanical polishing (CMP), or other suitable planarization techniques, so as to expose a top surface of the semiconductor layer 603. Portions of the dielectric layer that remain in the recesses respectively serve as the first dielectric films 611 and the second dielectric film 612. In some embodiments, the dielectric layer may include, for example, silicon oxide, silicon nitride, silicon oxynitride, high dielectric constant materials, other suitable materials, or combinations thereof.

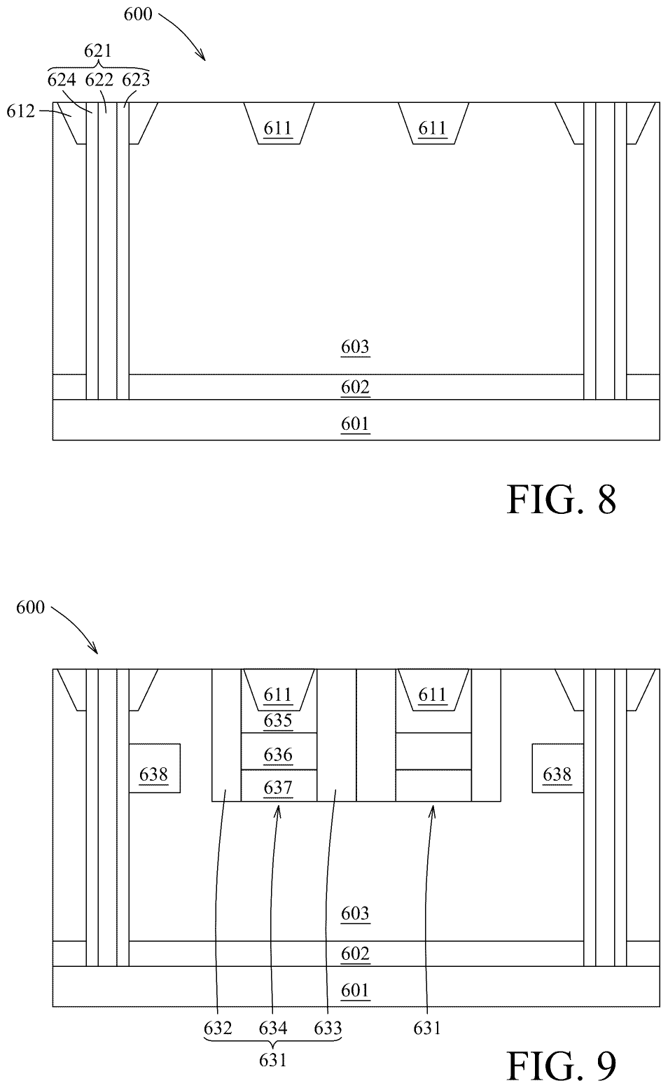

Referring to FIGS. 5 and 8, the method 500 then proceeds to step 53, where an isolation structure 621 is formed. The isolation structure 621 penetrates the second dielectric film 612, the semiconductor layer 603 and the buried insulation layer 602, and includes a conductive element 622, an inner dielectric element 623 and an outer dielectric element 624. The conductive element 622 has a ring shape, and encloses the first dielectric films 611. The inner dielectric element 623 covers an inner surface of the conductive element 622. The outer dielectric element 624 covers an outer surface of the conductive element 622. The second dielectric film 612 and the isolation structure 621 would cooperatively serve as the isolation feature 15 of the semiconductor device depicted in FIG. 1. In some embodiments, the isolation structure 621 may be formed by: (a) etching the second dielectric film 612, the semiconductor layer 603 and the buried insulation layer 602 to form a recess using, for example, dry etching, wet etching, reactive ion etching (RIE), atomic layer etching (ALE), other suitable techniques, or combinations thereof; (b) conformally depositing a dielectric layer for forming the inner dielectric element 623 and the outer dielectric element 624 on the semiconductor layer 603, the first dielectric films 611 and second dielectric film 612 and in the recess using, for example, physical vapor deposition (PVD), chemical vapor deposition (CVD), atomic layer deposition (ALD), plasma-enhanced chemical vapor deposition (PECVD), plasma-enhanced atomic layer deposition (PEALD), other suitable techniques, or combinations thereof; (c) removing horizontal portions of the dielectric layer using, for example, dry etching, wet etching, reactive ion etching (RIE), atomic layer etching (ALE), other suitable techniques, or combinations thereof, so as to form the inner dielectric element 623 and the outer dielectric element 624; (d) depositing a conductive layer for forming the conductive element 622 on the semiconductor layer 603, the first dielectric films 611, the second dielectric film 612, the inner dielectric element 623 and the outer dielectric element 624 and in the recess using, for example, chemical vapor deposition (CVD), atomic layer deposition (ALD), other suitable techniques, or combinations thereof; and (e) removing an excess of the conductive layer using, for example, chemical mechanical polishing (CMP), or other suitable planarization techniques, so as to expose top surfaces of the semiconductor layer 603, the first dielectric films 611, the second dielectric film 612, the inner dielectric element 623 and the outer dielectric element 624. A portion of the conductive layer that remains in the recess serves as the conductive element 622. In some embodiments, the dielectric layer may include, for example, silicon oxide, silicon nitride, silicon oxynitride, high dielectric constant materials, other suitable materials, or combinations thereof. In some embodiments, the conductive layer may include, for example, polysilicon, metal (e.g., tungsten (W), aluminum (Al) or the like), a metal compound (e.g., titanium nitride (TiN), titanium silicide (TiSi) or the like), other suitable materials, or combinations thereof.

Referring to FIGS. 5 and 9, the method 500 then proceeds to step 54, where a plurality of drift regions 631 and a plurality of lower well regions 638 are formed in the semiconductor layer 603. Each of the drift regions 631 corresponds to a respective one of the first dielectric films 611, and includes a first side well 632, a second side well 633 and a well stack 634. With respect to each of the drift regions 631: the well stack 634 is disposed between the first side well 632 and the second side well 633, and includes a first intermediate well 635, a second intermediate well 636 and a third intermediate well 637; the first intermediate well 635, the second intermediate well 636 and the third intermediate well 637 are laterally disposed and stacked from top to bottom in the given order; and the first intermediate well 635 covers bottom and side surfaces of the corresponding dielectric film 611. Each of the lower well regions 638 corresponds to a respective one of the first dielectric films 611, is disposed aside the corresponding first side well 632 and opposite to the corresponding well stack 634, and is spaced apart from the corresponding first side well 632 by the semiconductor layer 603. The drift regions 631 would respectively serve as the drift regions 141 of the transistors 14 of the semiconductor device depicted in FIG. 1. The lower well regions 638 would respectively serve as the second well regions 144 of the transistors 14 of the semiconductor device depicted in FIG. 1. In some embodiments, the first side wells 632, the second side wells 633, the first intermediate wells 635, the second intermediate wells 636 and the third intermediate wells 637 of the drift regions 631 and the lower well regions 638 may be formed using, for example, ion implantation, other suitable techniques, or combinations thereof. In some embodiments, the first side wells 632, the second side wells 633 and the second intermediate wells 636 of the drift regions 631 may be doped with n-type impurities (e.g., phosphorous (P), antimony (Sb), arsenic (As) or the like), and the first intermediate wells 635 and the third intermediate wells 637 of the drift regions 631 and the lower well regions 638 may be doped with p-type impurities (e.g., boron (B), aluminum (Al), gallium (Ga) or the like).

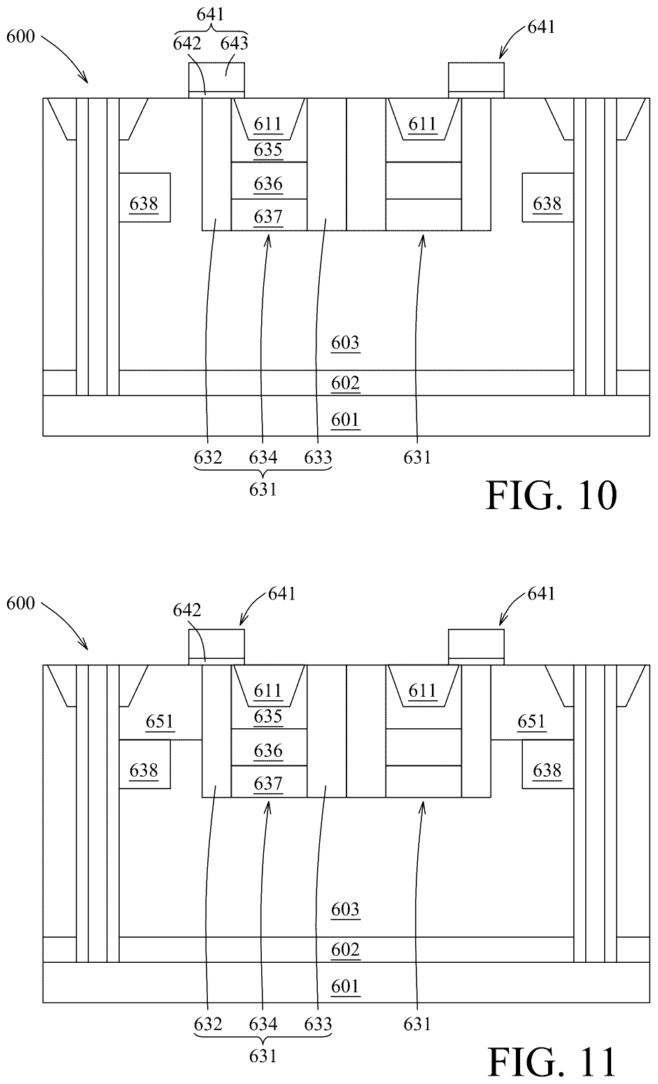

Referring to FIGS. 5 and 10, the method 500 then proceeds to step 55, where a plurality of gate structures 641 are formed on the semiconductor structure 600 depicted in FIG. 9. Each of the gate structures 641 corresponds to a respective one of the first dielectric films 611, and includes a gate dielectric 642 and a gate electrode 643. With respect to each of the gate structures 641, the gate dielectric 1481 is disposed over a portion of the semiconductor layer 603 that is adjacent to the corresponding first side well 632 and opposite to the corresponding well stack 634; and the gate electrode 643 is disposed on the gate dielectric 642, and is spaced apart by the gate dielectric 642 from the portion of the semiconductor layer 603 that is adjacent to the corresponding first side well 632 and opposite to the corresponding well stack 634. The gate structures 641 would respectively serve as the gate structures 148 of the transistors 14 of the semiconductor device depicted in FIG. 1. In some embodiments, the gate structures 641 may be formed by: (a) depositing a dielectric layer for forming the gate dielectrics 642 of the gate structures 641 on the semiconductor structure 600 depicted in FIG. 9 using, for example, physical vapor deposition (PVD), chemical vapor deposition (CVD), atomic layer deposition (ALD), plasma-enhanced chemical vapor deposition (PECVD), plasma-enhanced atomic layer deposition (PEALD), other suitable techniques, or combinations thereof; (b) depositing a conductive layer for forming the gate electrodes 643 of the gate structures 641 on the dielectric layer using, for example, physical vapor deposition (PVD), chemical vapor deposition (CVD), atomic layer deposition (ALD), plasma-enhanced chemical vapor deposition (PECVD), plasma-enhanced atomic layer deposition (PEALD), other suitable techniques, or combinations thereof; and (c) patterning the conductive layer and the dielectric layer using, for example, a photolithography process and an etching process, so as to form the gate dielectrics 642 and the gate electrodes 643 of the gate structures 641. For example, the photolithography process may include, but is not limited to, coating the conductive layer with a photoresist, soft-baking, exposing the photoresist through a photomask, post-exposure baking, developing the photoresist, and hard-baking, so as to form a patterned photoresist. The etching process may be implemented by etching the conductive layer and the dielectric layer through the patterned photoresist using, for example, dry etching, wet etching, reactive ion etching (RIE), atomic layer etching (ALE), other suitable techniques, or combinations thereof. The patterned photoresist may be removed after the etching process. In some embodiments, the dielectric layer may include, for example, Hf-based dielectric materials, Zr-based dielectric materials, Al-based dielectric materials, Ti-based dielectric materials, Ba-based dielectric materials, RE element-based dielectric materials, nitrides, other suitable high dielectric constant materials, or combinations thereof. In some embodiments, the conductive layer may include, for example, a metal (e.g., copper, aluminum, titanium, tantalum, cobalt, tungsten, or the like, or alloys thereof), polysilicon, metal-containing nitrides (e.g., TaN), metal-containing silicides (e.g., NiSi), metal-containing carbides (e.g., TaC), other suitable conductive materials, or combinations thereof.

Referring to FIGS. 5 and 11, the method 500 then proceeds to step 56, where a plurality of upper well regions 651 are formed in the semiconductor layer 603. Each of the upper well regions 651 corresponds to a respective one of the first dielectric films 611, is disposed between the corresponding lower well region 638 and the corresponding gate dielectric 642, and is in contact with the corresponding first side well 632. The upper well regions 651 would respectively serve as the first well regions 143 of the transistors 14 of the semiconductor device depicted in FIG. 1. In some embodiments, the upper well regions 651 may be formed using, for example, ion implantation, other suitable techniques, or combinations thereof. In some embodiments, the upper well regions 651 may be doped with p-type impurities (e.g., boron (B), aluminum (Al), gallium (Ga) or the like).

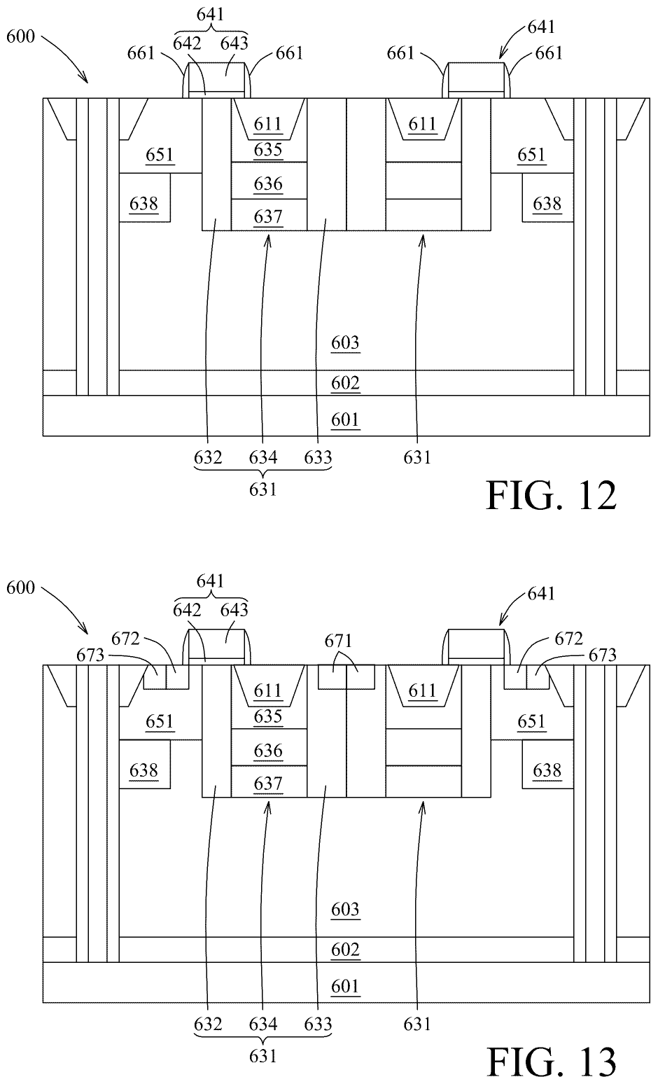

Referring to FIGS. 5 and 12, the method 500 then proceeds to step 57, where a plurality of gate spacers 661 are formed. The gate spacers 661 laterally cover the gate dielectrics 642 and the gate electrodes 643 of the gate structures 641. The gate spacers 661 would respectively serve as the gate spacers 149 of the transistors 14 of the semiconductor device depicted in FIG. 1. In some embodiments, the gate spacers 661 may be formed by: (a) conformally depositing a dielectric layer for forming the gate spacers 661 on the semiconductor structure 600 depicted in FIG. 11 using, for example, physical vapor deposition (PVD), chemical vapor deposition (CVD), atomic layer deposition (ALD), plasma-enhanced chemical vapor deposition (PECVD), plasma-enhanced atomic layer deposition (PEALD), other suitable techniques, or combinations thereof; and (b) removing horizontal portions of the dielectric layer using, for example, dry etching, wet etching, reactive ion etching (RIE), atomic layer etching (ALE), other suitable techniques, or combinations thereof, so as to form the gate spacers 661. In some embodiments, the dielectric layer may include, for example, silicon nitride, silicon oxycarbide, silicon oxycarbonitride, silicon carbonitride, other suitable materials, or combinations thereof.

Referring to FIGS. 5 and 13, the method 500 then proceeds to step 58, where a plurality of drain regions 671, a plurality of source regions 672 and a plurality of bulk regions 673 are formed. Each of the drain regions 671 corresponds to a respective one of the first dielectric films 611, and is disposed in the corresponding second side well 633. Each of the source regions 672 corresponds to a respective one of the first dielectric films 611, is disposed in the corresponding upper well region 651, and is close to the corresponding gate dielectric 642. Each of the bulk regions 673 corresponds to a respective one of the first dielectric films 611, is disposed in the corresponding upper well region 651, and is distal from the corresponding gate dielectric 642. The drain regions 671 would respectively serve as the drain regions 145 of the transistors 14 of the semiconductor device depicted in FIG. 1. The source regions 672 would respectively serve as the source regions 146 of the transistors 14 of the semiconductor device depicted in FIG. 1. The bulk regions 673 would respectively serve as the bulk regions 147 of the transistors 14 of the semiconductor device depicted in FIG. 1. In some embodiments, the drain regions 671, the source regions 672 and the bulk regions 673 may be formed using, for example, ion implantation, other suitable techniques, or combinations thereof. In some embodiments, the drain regions 671 and the source regions 672 may be doped with n-type impurities (e.g., phosphorous (P), antimony (Sb), arsenic (As) or the like), and the bulk regions 673 may be doped with p-type impurities (e.g., boron (B), aluminum (Al), gallium (Ga) or the like).

After step 58 is executed, a resist protection oxide (RPO) and a plurality of contacts may be formed on the semiconductor structure 600 depicted in FIG. 13, so that each of the gate electrodes 643 of the gate structures 641, the drain regions 671 and the source regions 672 can be connected to another component.

In accordance with some embodiments of the present disclosure, a semiconductor device includes a semiconductor layer, a drift region formed in the semiconductor layer, and a dielectric film formed in the drift region. The drift region includes a first side well, a second side well and a well stack. The first side well has a first type conductivity. The second side well has the first type conductivity. The well stack is disposed laterally between the first side well and the second side well, and includes a plurality of intermediate wells that are stacked from top to bottom. A topmost one of the intermediate wells has a second type conductivity opposite to the first type conductivity, and covers bottom and side surfaces of the dielectric film. Two adjacent ones of the intermediate wells have different type conductivities.

In accordance with some embodiments of the present disclosure, one of the side surfaces of the dielectric film is in contact with the topmost one of the intermediate wells, and is spaced apart from one of the first side well and the second side well that faces the one of the side surfaces of the dielectric film.

In accordance with some embodiments of the present disclosure, one of the side surfaces of the dielectric film is in contact with the topmost one of the intermediate wells and one of the first side well and the second side well that faces the one of the side surfaces of the dielectric film.

In accordance with some embodiments of the present disclosure, the semiconductor device further includes a first well region. The first well region is formed in the semiconductor layer, is disposed aside the first side well and opposite to the well stack, and has the second type conductivity.

In accordance with some embodiments of the present disclosure, the first type conductivity is an n-type conductivity, and the second type conductivity is a p-type conductivity.

In accordance with some embodiments of the present disclosure, the semiconductor device further includes a second well region. The second well region is formed in the semiconductor layer, is disposed below the first well region, is spaced apart from the first side well, and has the second type conductivity.

In accordance with some embodiments of the present disclosure, a volume of the second well region is smaller than a volume of the first well region.

In accordance with some embodiments of the present disclosure, the first type conductivity is a p-type conductivity, and the second type conductivity is an n-type conductivity.

In accordance with some embodiments of the present disclosure, the semiconductor device further includes a drain region and a source region. The drain region is formed in the second side well, and has the first type conductivity. The source region is formed in the first well region, and has the first type conductivity.

In accordance with some embodiments of the present disclosure, a semiconductor device includes a semiconductor layer, a drift region, a dielectric film, a first well region, a drain region, a source region and a gate structure. The drift region is formed in the semiconductor layer. The dielectric film is formed in the drift region. The drift region includes a first side well, a second side well and a well stack. Thea first side well has a first type conductivity. The second side well has the first type conductivity. The well stack is disposed laterally between the first side well and the second side well, and includes a plurality of intermediate wells that are stacked from top to bottom. A topmost one of the intermediate wells has a second type conductivity opposite to the first type conductivity, and covers bottom and side surfaces of the dielectric film. Two adjacent ones of the intermediate wells have different type conductivities. The first well region is formed in the semiconductor layer, is disposed aside the first side well and opposite to the well stack, and has the second type conductivity. The drain region is formed in the second side well, and has the first type conductivity. The source region is formed in the first well region, and has the first type conductivity. The gate structure is disposed over a portion of the first well region that is between the source region and the first side well.

In accordance with some embodiments of the present disclosure, each of the side surfaces of the dielectric film is in contact with the topmost one of the intermediate wells, and is spaced apart from one of the first side well and the second side well that faces the side surface of the dielectric film.

In accordance with some embodiments of the present disclosure, each of the side surfaces of the dielectric film is in contact with the topmost one of the intermediate wells and one of the first side well and the second side well that faces the side surface of the dielectric film.

In accordance with some embodiments of the present disclosure, the first type conductivity is an n-type conductivity, and the second type conductivity is a p-type conductivity.

In accordance with some embodiments of the present disclosure, the semiconductor device further includes a second well region. The second well region is formed in the semiconductor layer, is disposed below the first well region, is spaced apart from the first side well, and has the second type conductivity.

In accordance with some embodiments of the present disclosure, a volume of the second well region is smaller than a volume of the first well region.

In accordance with some embodiments of the present disclosure, the first type conductivity is a p-type conductivity, and the second type conductivity is an n-type conductivity.

In accordance with some embodiments of the present disclosure, a method for manufacturing a semiconductor device includes: forming a dielectric film in a semiconductor layer; and forming a drift region in the semiconductor layer. The drift region includes a first side well, a second side well and a well stack. The first side well has a first type conductivity. The second side well has the first type conductivity. The well stack is disposed laterally between the first side well and the second side well, and includes a plurality of intermediate wells that are stacked from top to bottom. A topmost one of the intermediate wells has a second type conductivity opposite to the first type conductivity, and covers bottom and side surfaces of the dielectric film. Two adjacent ones of the intermediate wells have different type conductivities.

In accordance with some embodiments of the present disclosure, the method further includes: forming a first well region in the semiconductor layer, where the first well region has the second type conductivity, and is disposed aside the first side well and opposite to the well stack.

In accordance with some embodiments of the present disclosure, the method further includes: before forming the first well region, forming a second well region in the semiconductor layer, where the second well region has the second type conductivity, is disposed below a portion of the semiconductor layer in which the first well region is to be formed, and is spaced apart from the first side well.

In accordance with some embodiments of the present disclosure, the method further includes: before forming the first well region, forming a gate structure on the semiconductor layer, where the gate structure is disposed over a portion of the semiconductor layer that is close to the first side well and opposite to the well stack.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a semiconductor layer;
a drift region formed in the semiconductor layer; and
a dielectric film formed in the drift region;
wherein the drift region includes
a first side well having a first type conductivity,
a second side well having the first type conductivity, and
a well stack disposed laterally between the first side well and the second side well, and including a plurality of intermediate wells that are stacked from top to bottom, where a topmost one of the intermediate wells has a second type conductivity opposite to the first type conductivity, and covers bottom and side surfaces of the dielectric film, and two adjacent ones of the intermediate wells have different type conductivities.

2. The semiconductor device according to claim 1, wherein:
one of the side surfaces of the dielectric film is in contact with the topmost one of the intermediate wells, and is spaced apart from one of the first side well and the second side well that faces the one of the side surfaces of the dielectric film.

3. The semiconductor device according to claim 1, wherein:
one of the side surfaces of the dielectric film is in contact with the topmost one of the intermediate wells and one of the first side well and the second side well that faces the one of the side surfaces of the dielectric film.

4. The semiconductor device according to claim 1, further comprising:
a first well region formed in the semiconductor layer, disposed aside the first side well and opposite to the well stack, and having the second type conductivity.

5. The semiconductor device according to claim 4, wherein:
the first type conductivity is an n-type conductivity; and
the second type conductivity is a p-type conductivity.

6. The semiconductor device according to claim 5, further comprising:
a second well region formed in the semiconductor layer, disposed below the first well region, spaced apart from the first side well, and having the second type conductivity.

7. The semiconductor device according to claim 6, wherein:
a volume of the second well region is smaller than a volume of the first well region.

8. The semiconductor device according to claim 4, wherein:
the first type conductivity is a p-type conductivity; and
the second type conductivity is an n-type conductivity.

9. The semiconductor device according to claim 4, further comprising:
a drain region formed in the second side well, and having the first type conductivity; and
a source region formed in the first well region, and having the first type conductivity.

10. A semiconductor device comprising:
a semiconductor layer;
a drift region formed in the semiconductor layer;
a dielectric film formed in the drift region;
the drift region including
a first side well having a first type conductivity,
a second side well having the first type conductivity, and
a well stack disposed laterally between the first side well and the second side well, and including a plurality of intermediate wells that are stacked from top to bottom, where a topmost one of the intermediate wells has a second type conductivity opposite to the first type conductivity, and covers bottom and side surfaces of the dielectric film, and two adjacent ones of the intermediate wells have different type conductivities;
a first well region formed in the semiconductor layer, disposed aside the first side well and opposite to the well stack, and having the second type conductivity;
a drain region formed in the second side well, and having the first type conductivity;
a source region formed in the first well region, and having the first type conductivity; and
a gate structure disposed over a portion of the first well region that is between the source region and the first side well.

11. The semiconductor device according to claim 10, wherein:
each of the side surfaces of the dielectric film is in contact with the topmost one of the intermediate wells, and is spaced apart from one of the first side well and the second side well that faces the side surface of the dielectric film.

12. The semiconductor device according to claim 10, wherein:
each of the side surfaces of the dielectric film is in contact with the topmost one of the intermediate wells and one of the first side well and the second side well that faces the side surface of the dielectric film.

13. The semiconductor device according to claim 10, wherein:
the first type conductivity is an n-type conductivity; and
the second type conductivity is a p-type conductivity.

14. The semiconductor device according to claim 13, further comprising:
a second well region formed in the semiconductor layer, disposed below the first well region, spaced apart from the first side well, and having the second type conductivity.

15. The semiconductor device according to claim 14, wherein:
a volume of the second well region is smaller than a volume of the first well region.

16. The semiconductor device according to claim 10, wherein:
the first type conductivity is a p-type conductivity; and
the second type conductivity is an n-type conductivity.

17. A method for manufacturing a semiconductor device, comprising:
forming a dielectric film in a semiconductor layer; and
forming a drift region in the semiconductor layer, where the drift region includes
a first side well having a first type conductivity,
a second side well having the first type conductivity, and
a well stack disposed laterally between the first side well and the second side well, and including a plurality of intermediate wells that are stacked from top to bottom, where a topmost one of the intermediate wells has a second type conductivity opposite to the first type conductivity, and covers bottom and side surfaces of the dielectric film, and two adjacent ones of the intermediate wells have different type conductivities.

18. The method according to claim 17, further comprising:
forming a first well region in the semiconductor layer, where the first well region has the second type conductivity, and is disposed aside the first side well and opposite to the well stack.

19. The method according to claim 18, further comprising:
before forming the first well region, forming a second well region in the semiconductor layer, where the second well region has the second type conductivity, is disposed below a portion of the semiconductor layer in which the first well region is to be formed, and is spaced apart from the first side well.

20. The method according to claim 18, further comprising:
before forming the first well region, forming a gate structure on the semiconductor layer, where the gate structure is disposed over a portion of the semiconductor layer that is close to the first side well and opposite to the well stack.
